(19) United States
(12) Patent Application Publication
(10) Pub. No.: US 2014/0151841 A1
(43) Pub. Date: Jun. 5, 2014

(54) SEMICONDUCTOR DEVICES HAVING A POSITIVE-BEVEL TERMINATION OR A NEGATIVE-BEVEL TERMINATION AND THEIR MANUFACTURE

(71) Applicant: North Carolina State University, Raleigh, NC (US)

(72) Inventors: Xing Huang, Raleigh, NC (US); B. Jayant Baliga, Raleigh, NC (US); Alex Qin Huang, Cary, NC (US)

(21) Appl. No.: 14/094,189

(22) Filed: Dec. 2, 2013

Related U.S. Application Data
(60) Provisional application No. 61/732,310, filed on Dec. 1, 2012.
(60) Provisional application No. 61/732,311, filed on Dec. 1, 2012.

(51) Int. Cl. H01L 21/78; H01L 29/06

(52) U.S. Cl. CPC H01L 21/78; H01L 29/0688
USPC 257/471; 438/462

(57) ABSTRACT

Disclosed herein are techniques of manufacturing semiconductor devices having a positive-bevel termination and/or a negative-bevel termination. In a particular example, techniques are disclosed for manufacture of a chip-size SiC device having an orthogonal positive-bevel termination used for the reverse blocking junction. The edge termination may be formed, for example, by cutting across a SiC wafer with a V-shaped dicing tool or blade. The cut may be performed by any suitable dicing tool. The cut may be across a p-n junction for forming positive-bevel termination. Subsequently, a surface of the termination may be etched for removing damage caused by the cutting process.

### CROSS-REFERENCE TO RELATED APPLICATIONS

This application claims priority to U.S. Provisional Application No. 61/732,310, titled SEMICONDUCTOR DEVICES HAVING A POSITIVE-BEVEL TERMINATION OR A NEGATIVE-BEVEL TERMINATION AND THEIR MANUFACTURE and filed on Dec. 1, 2012, and U.S. Provisional Application No. 61/732,311, titled SEMICONDUCTOR DEVICES HAVING A POSITIVE-BEVEL TERMINATION OR A NEGATIVE-BEVEL TERMINATION AND THEIR MANUFACTURE and filed on Dec. 1, 2012; the contents of which are hereby incorporated by reference in their entireties.

### FEDERALLY SPONSORED RESEARCH OR DEVELOPMENT

The technology disclosed herein was made with government support under award number EEC-0812121 awarded by the National Science Foundation (NSF). The United States government may have certain rights in the technology.

### TECHNICAL FIELD

The present disclosure relates to semiconductor devices and their manufacture. More particularly, the present disclosure relates to manufacture of semiconductor devices having a positive-bevel termination and/or a negative-bevel termination.

### BACKGROUND

The next-generation power semiconductor, 4H-silicon carbide (SiC), is a promising material for future solid-state power switches in energy conversion and fault protection applications. For example, a 15 kV 100 A ultra-fast solid-state switch with symmetric blocking capabilities is desired in the fault interruption devices (FIDs) of 7.2 kV AC transmission lines. With an asymmetric blocking switch, a 15 kV diode may be placed in series with a switch in order to provide reverse blocking capability. The forward voltage drop of the series diode doubles the conduction loss within the FIDs. A reverse blocking switch is therefore highly desirable to minimize power losses.

Unlike silicon reverse blocking insulated-gate bipolar transistors (IGBTs) that use deep diffusion isolation or trench isolation, the material properties of SiC make these techniques impractical due to fabrication challenges such as virtually no dopant diffusion and lack of a well-established deep reactive-ion etching (RIE) process.

Another commonly used technique for the reverse blocking capability of silicon devices is positive-bevel termination, which is usually used for high-power diodes and thyristors fabricated from an entire silicon wafer due to their high current ratings. This kind of positive bevel can be formed by grit blasting of the periphery of the silicon wafers while it is spinning. The abrasion damage is then removed by the following wet etching of the silicon. However, for applications such as SiC-based FIDs, this approach is not practical due to the smaller chip size and lower current ratings of SiC devices. Although 30°-80° bevels have been obtained on SiC by SF₆/O₂ plasma RIE with a wet-etched SiO₂ layer as the mask, the etching selectivity of up to 6.5 is still not practical for high-voltage SiC devices with a thick epitaxial layer.

In view of the foregoing, it is desirable to provide improved techniques for manufacture of semiconductor devices with positive-bevel termination. In addition, it is desirable to provide improved techniques for manufacture of semiconductor devices with negative-bevel termination.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Disclosed herein are techniques of manufacturing semiconductor devices having a positive-bevel termination and/or a negative-bevel termination. In a particular example, techniques are disclosed for manufacture of a chip-size SiC device having an orthogonal positive-bevel termination used for the reverse blocking junction. The edge termination may be formed, for example, by cutting across a SiC wafer with a V-shaped dicing tool or blade. The cut may be performed by any suitable dicing tool. The cut may be made across a p-n junction for forming positive-bevel termination. Subsequently, a surface of the termination may be etched for removing damage caused by the cutting process.

In accordance with embodiments of the present disclosure, a method of manufacturing a semiconductor device may include providing a wafer having disposed thereon semiconductor layers forming one of a p-n junction and a Schottky barrier junction. The method may include cutting across the p-n junction or the Schottky barrier for forming a substantially orthogonal positive-bevel termination.

In accordance with other embodiments of the present disclosure, a method of manufacturing a semiconductor device may include providing a wafer having disposed thereon semiconductor layers forming a p-n junction. The method may include cutting across the p-n junction for forming a negative-bevel termination.

### BRIEF DESCRIPTION OF THE DRAWINGS

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1A depicts a scanning electron microscope (SEM) image of a top view of orthogonal positive-bevels of semiconductor devices in accordance with embodiments of the present disclosure;

FIG. 1B depicts an SEM image of a top view of the semiconductor devices shown in FIG. 1A prior to RIE treatment;

FIG. 1C depicts cross-sectional views of an NPN symmetric blocking structure and a P⁺P⁻N⁺ diode in accordance with embodiments of the present disclosure;

FIG. 2 is a graph of leakage current measurement before and after RIE (normalized to periphery);

FIG. 3 is a graph showing a surface electric fields of 30°, 45°, and 60° bevels at 1100 V bias;

FIG. 4 is a graph comparing an analytical model and numerical simulation;

FIG. 5 is a technology computer aided design (TCAD) 3-D simulation of orthogonal joint of two 45° bevels at 1100 V;

FIG. 6 depict diagrams of an example NPN symmetric blocking structure and P⁺P⁻N⁺ diode;

FIG. 7 is a graph showing reverse blocking leakage current of an NPN structure before and after RIE;

FIG. 8 is a histogram of log (I_{reverse, leakage}) before and after RIE;

FIG. 9 is a graph of symmetric blocking characteristics of an NPN structure from −1100 V to 1100V;

FIG. 10 is a graph of reverse characteristics of P+P−N+ diode with 1610 V breakdown;

FIG. 11 is a cross-sectional view of a semiconductor device that has a composite negative and positive-bevel terminations and manufactured in accordance with embodiments of the present disclosure; and

FIG. 12 is a cross-sectional view of a P⁺N⁻N⁺ diode in accordance with embodiments of the present disclosure.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies. Moreover, although the term “step” may be used herein to connote different aspects of methods employed, the term should not be interpreted as implying any particular order among or between various steps herein disclosed unless and except when the order of individual steps is explicitly described.

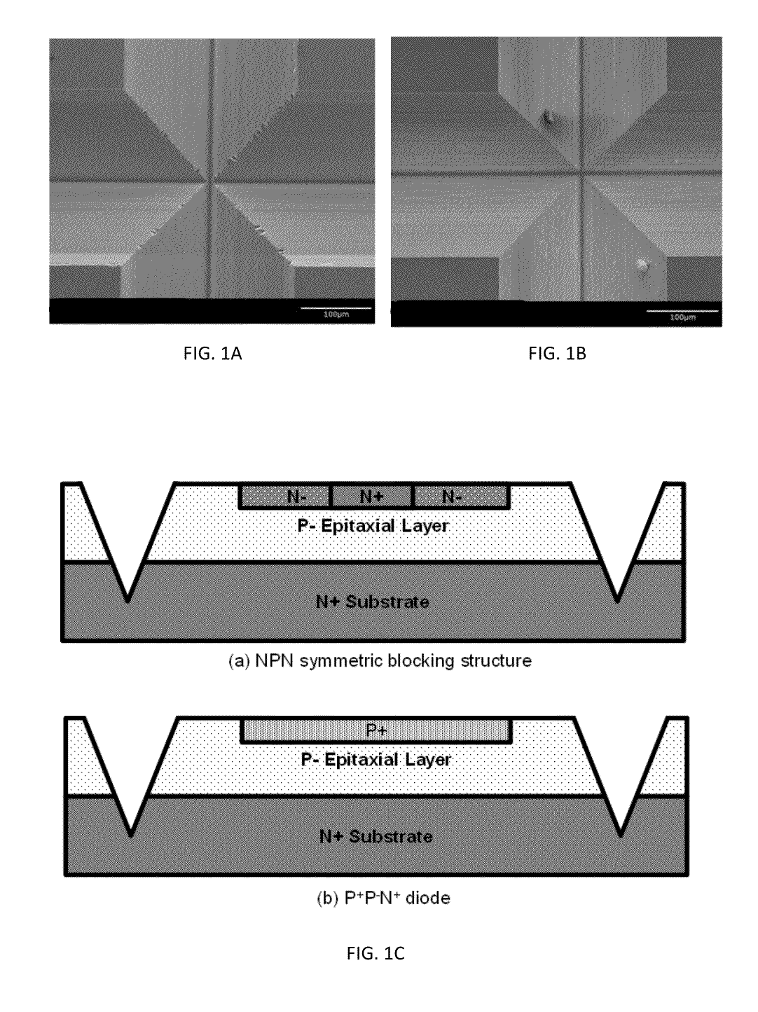

FIG. 1A depicts an SEM image of a top view of orthogonal positive-bevels of semiconductor devices in accordance with embodiments of the present disclosure. The orthogonal bevels can result from manufacture techniques disclosed herein. A manufacture method may include providing a wafer having disposed thereon semiconductor layers forming a p-n junction. In this example, the wafer is a 350 μm thick N⁺4H—SiC substrate with a 15.8 μm p-type epitaxial layer. The epitaxial layer has an aluminum doping concentration of 6.1×10¹⁵ cm⁻³. The positive-bevel edge termination, as shown in the example of FIG. 1A, may be formed by sawing deep V-shaped trenches into the wafer. In this example, the positive-bevel edge termination was formed by sawing 100 μm deep V-shaped trenches into the SiC using a diamond-coated blade with a 45° angle. It should be appreciated by those of skill in the art that the edge termination may be formed by any suitable technique and at any suitable angle. The SiC wafer may subsequently be cut into 3 mm×3 mm squares.

Sawing may result in damage on the surface of the termination and scalloping at the intersection of the orthogonal saw cuts. In experiments, the breakdown voltage of the p-n junction was measured in Fluorinert liquid without any additional passivation. Because no field-stop P+ implantation and front-side metallization were made, the BV under DC bias was measured below 1000 V to avoid catastrophic failure at the tiny probe point. Over 50% of the measured devices were found to block 1000 V with a leakage current of 25 μA. The high leakage current for the assawed devices comes from the surface damage produced by the blade. On selected samples, the device breakdown was around 1050 V as limited by the reach through of the electric field to the probe point.

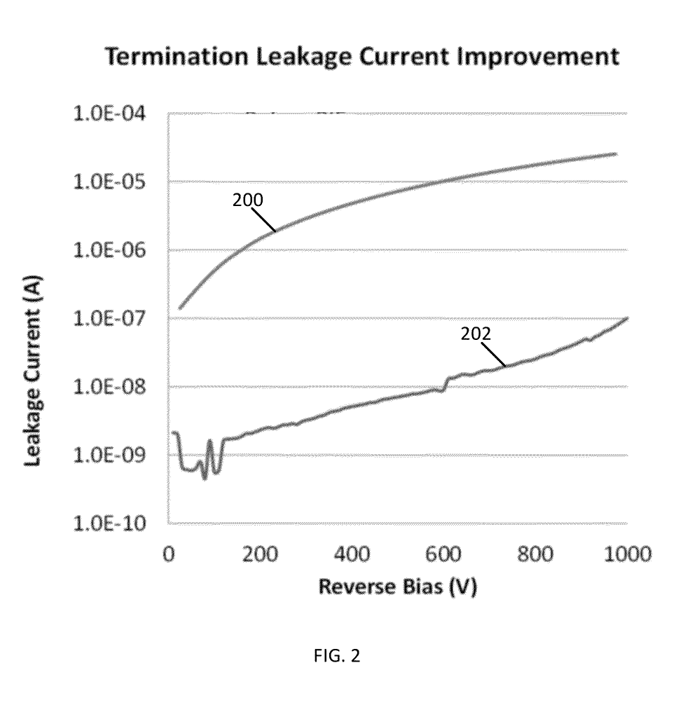

In order to reduce the effects of sawing damage, RIE or any suitable etching of the wafer may be performed. For example, RIE etching of a wafer may be performed in SF₆/O₂ plasma. In an example method that was performed to result in the device shown in FIG. 1A, a layer of 0.3 μm of SiC was removed from the surface. FIG. 2 which illustrates a graph of leakage current measurement before and after RIE (normalized to periphery). Referring to FIG. 2, line 200 indicates leakage current measurement before RIE, and line 202 indicates leakage current measurement after RIE. FIG. 2 demonstrates that the leakage current measured in Fluorinert liquid was reduced by 100-fold to 100 nA at 1000 V reverse bias. The leakage current density at 1000 V obtained by dividing the leakage current by the chip area is 300 μA/cm² before and 1 μ/cm² after the RIE treatment. Since most of the leakage comes from the bevel termination, it is also useful to normalize the leakage current to the termination periphery. The leakage current per unit length of the die periphery is 21 μA/cm before and 1 nA/cm after the RIE treatment.

FIG. 1B depicts an SEM image of a top view of the semiconductor devices shown in FIG. 1A prior to RIE treatment. The RIE treatment or any other suitable RIE treatment can reduce the impact of any wear in the saw blade or other cutting tool on the surface damage across the wafer.

FIG. 1C depicts cross-sectional views of an NPN symmetric blocking structure and a P⁺P⁻N⁺ diode in accordance with embodiments of the present disclosure. The NPN symmetric blocking structure is labeled (a). The P⁺P⁻N⁺ diode is labeled (b).

Experiments have demonstrated that a positive-bevel edge termination in accordance with the present disclosure can achieve high reverse blocking voltage on multiple SiC devices by sawing the wafer. It is recognized that the presence of a deep V-groove may degrade photoresist coverage and patterning during device fabrication. In addition, it is recognized that wafer breakage may occur due to the mechanical stress introduced by the V-groove. For these reasons, although no wafer cracking was observed in experiments, it is envisioned that the bevel termination can be manufactured at or near the end of the device fabrication. This technique can be used for any chip-size symmetric blocking devices such as, for example, IGBTs and thyristors. In addition, this technique can be used for high power P⁺P⁻N⁺ diode to terminate the deep pn junctions.

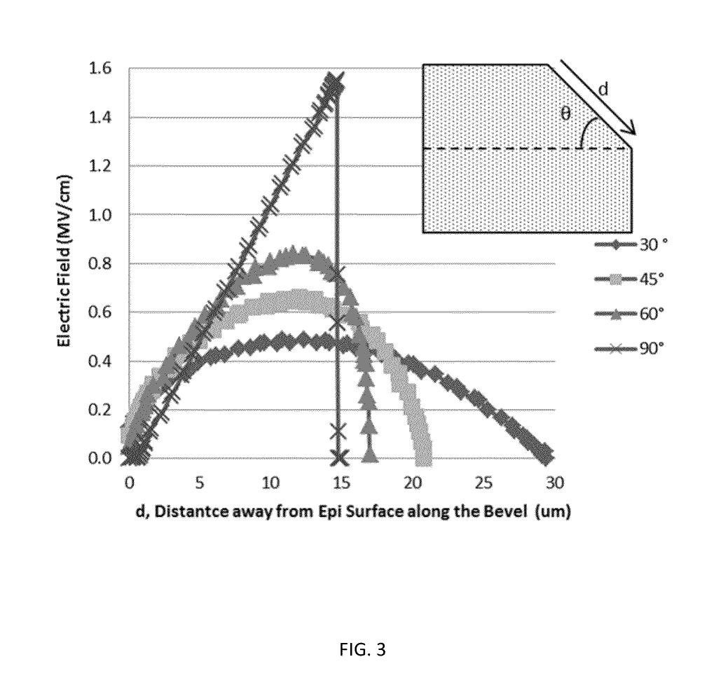

Simulations were performed to analyze the application of a positive-bevel termination to SiC devices. For example, 2-D numerical simulations were performed for the case of a 15.8 μm 6.1×10¹⁵ cm⁻³ p-type layer on an N⁺ substrate with various bevel angles. The electric field on the beveled surface was found to decrease with smaller bevel angles as shown in FIG. 3, which illustrates a graph showing a surface electric fields of 30°, 45°, and 60° bevels at 1100 V bias. The peak surface fields of 30°, 45°, and 60° bevels are respectively reduced to only 31.5%, 42.5%, and 54.1% of the bulk electric field (which is the same as for a 90° angle). The 2-D simulations of all bevel angles predict the onset of hard breakdowns at about 1050 V due to field reach through. Bevels of these angles or any other suitable angle may be manufactured and used in accordance with embodiments of the present disclosure.

An analytical model for the peak electric field at a positive-bevel termination may be represented by the following equation:

$${E}_{mS} = {E}_{mB} \frac{{W}_{S}}{{W}_{B}} = {E}_{mB} \frac{sin ( θ )}{1 + cos ( θ )}$$

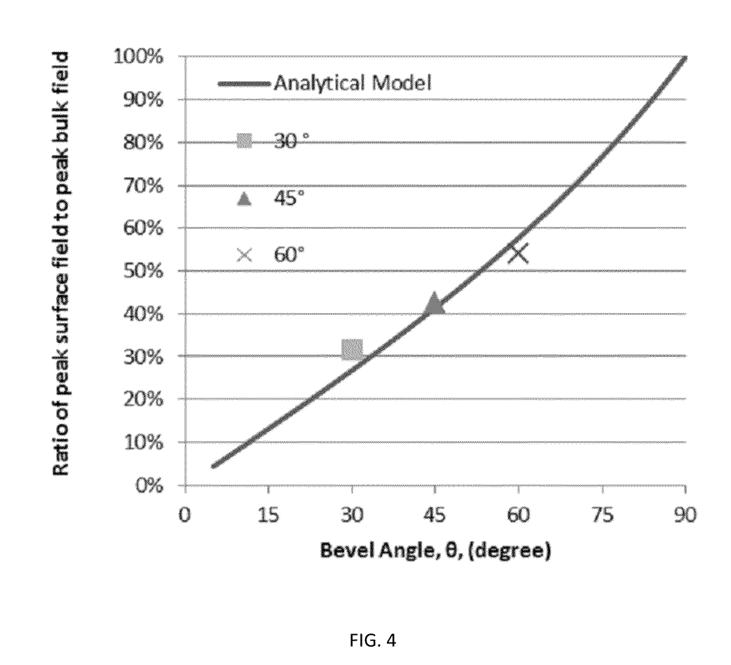

The prediction of this model are in good agreement with the results of the 2-D numerical simulations as shown in FIG. 4, which illustrates a graph comparing an analytical model and numerical simulation.

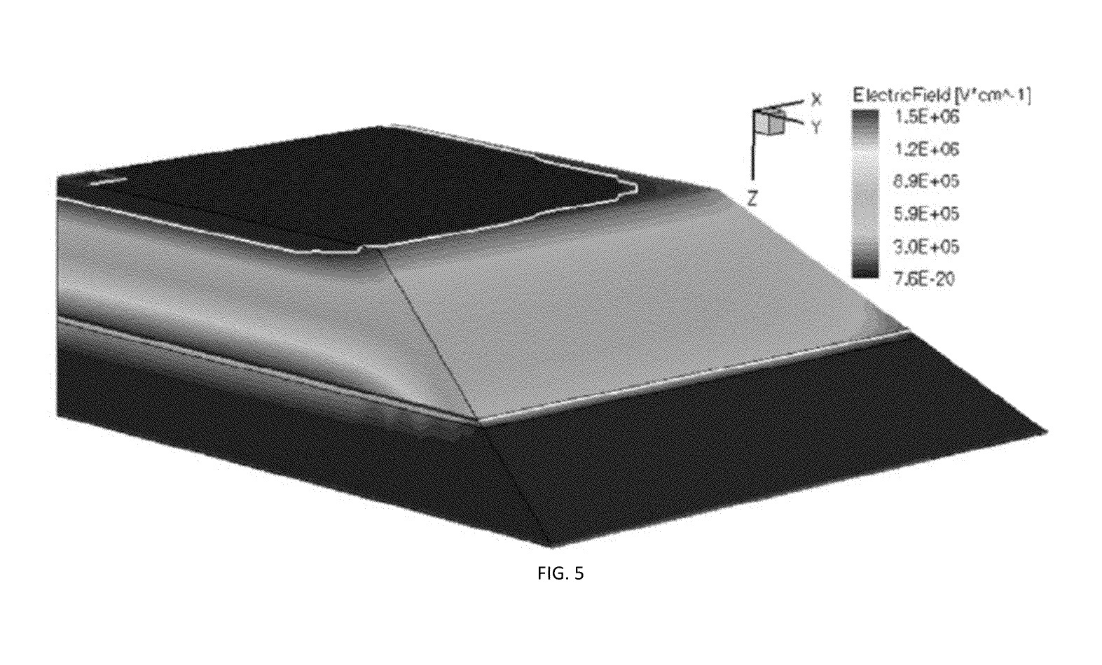

In the case of many edge terminations, the breakdown is initiated at the corners of the chip due to high junction curvature. For a positive-bevel termination in accordance with the present disclosure, the corners of the chip may be sharp right angles formed by two orthogonal saw cuts or any other suitable type of cut. In order to understand the impact of this structure, 3-D numerical simulations were performed for the case of 45° bevels. FIG. 5 illustrates a TCAD 3-D simulation of orthogonal joint of two 45° bevels at 1100 V. Referring to FIG. 5, it was demonstrated that the extension of depletion layer at the intersection of the two orthogonal bevels is even larger than that of the positive bevel at the edges of the chip. The numerical simulations indicate that the surface electric field at the corners is less than that at the edges. This implies that the breakdown of the SiC devices at the edges and corners of the chips can be prevented by using the proposed orthogonal positive-bevel termination since the maximum electric field is confined within the bulk.

In accordance with embodiments of the present disclosure, a symmetric blocking power semiconductor switch may be provided that has two edge terminations, one for the reverse blocking junction and the other for the forward blocking junction. The switch may have an orthogonal positive-bevel termination and a one-zone junction termination extension (JTE). The bevel may be formed by orthogonally sawing 45° V-shape trenches into a SiC wafer with a diamond-coated dicing blade or other suitable dicing tool. The surface damage may then be repaired with dry-etch in SF₆/O₂ plasma, which can reduce the leakage current by around two orders of magnitude. As limited by field reach-through, both the orthogonal positive-bevel and the JTE terminations show breakdown voltage of 1100 V. The orthogonal positive-bevel terminations of the NPN structures show as high as 90%. The P⁺P⁻N⁺ diode fabricated on the same wafer with the orthogonal positive-bevel termination shows 1610 V avalanche breakdown which is around 85% of ideal value. As a result of these techniques, symmetric blocking can be provided for the SiC device.

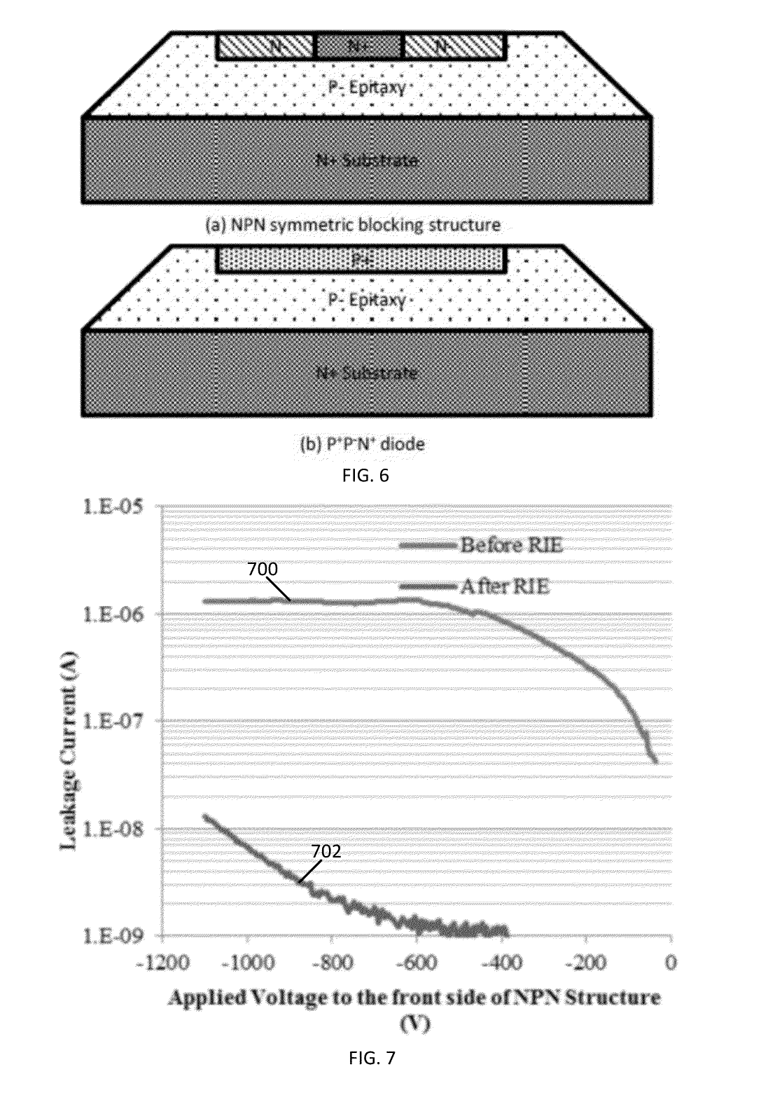

In an example, a 350 μm thick N⁺4H—SiC substrate with a 15.8 μm p-type epitaxial layer can be used. The epitaxial layer may have an aluminum doping concentration of 6.1×10¹⁵ cm⁻³. It should be understood to those of skill in the art that the substrate and epitaxial layer may be of any suitable type and thickness, and that the doping may be of any suitable concentration. Further, an NPN symmetric blocking structure with JTE termination and a P⁺P⁻N⁺ diode can be fabricated. FIG. 6 illustrates diagrams of an example NPN symmetric blocking structure and P⁺P⁻N⁺ diode. The implantations can be first conducted at room temperature using photoresist as the masks. Activation and annealing and thermal oxide passivation steps can then be performed. Subsequently, contact holes may be opened, and metallization may be patterned and annealed. Next, 100 μm deep V-shaped trenches may be sawed into the SiC wafer, which may then be treated with RIE in the SF₆/O₂ plasma. The dies may be cut into 3 mm×3 mm squares. According to a TCAD 3D simulation, when applying a negative bias at the front side of the NPN structure, the maximum field on the beveled surface is only 42.5% of that within the bulk (See e.g., FIG. 5). The breakdown and leakage measurement of the orthogonal positive-bevel terminations show reproducible results of reduced leakage current after RIE treatment. For example, FIG. 7 illustrates a graph showing reverse blocking leakage current of an NPN structure before and after RIE. Referring to FIG. 7, line 700 indicates leakage current measurement before RIE, and line 702 indicates leakage current measurement after RIE.

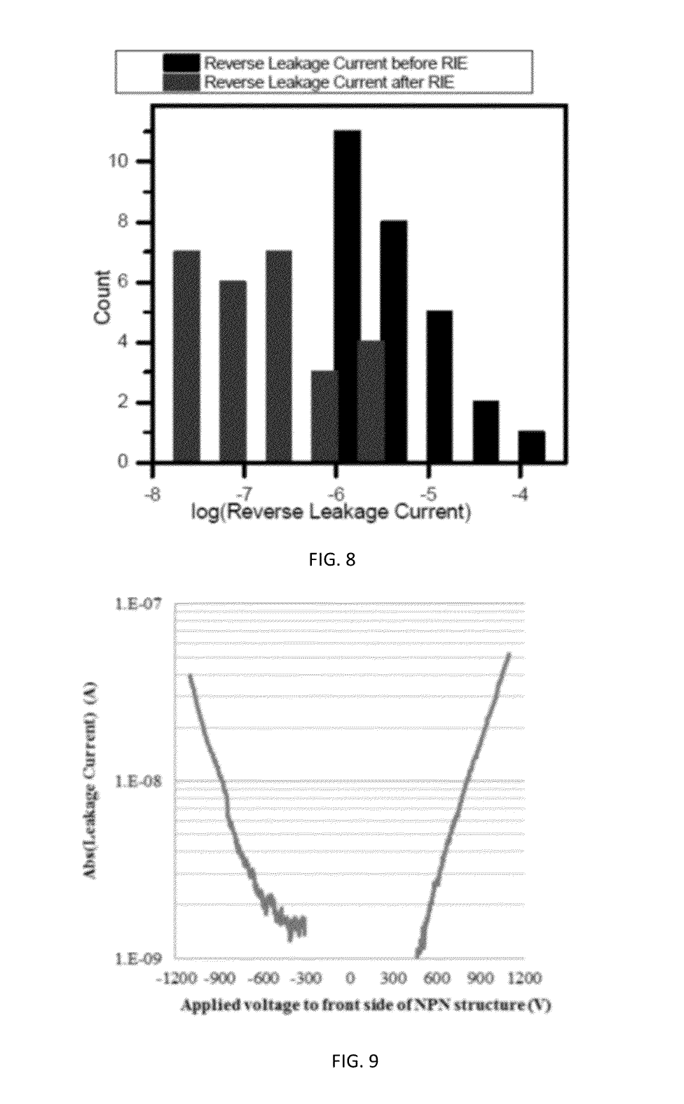

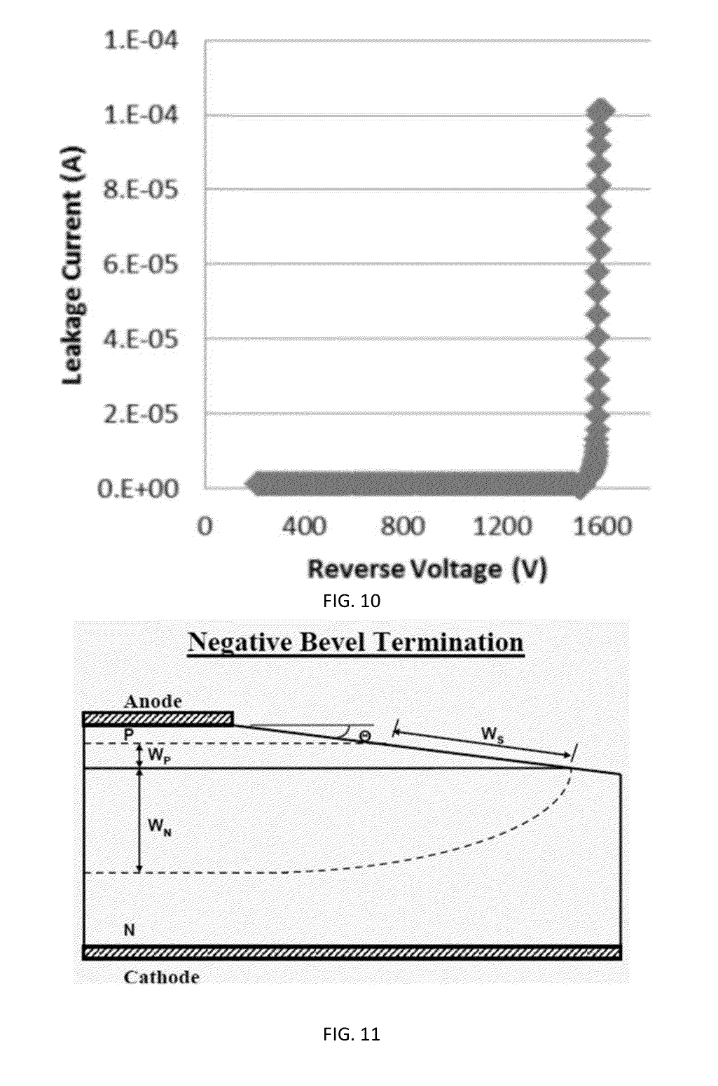

FIG. 8 illustrates a histogram of log (I_{reverse, leakage}) before and after RIE. The NPN symmetric blocking structure can block 1100 V in both directions as shown in FIG. 9, which illustrates a graph of symmetric blocking characteristics of an NPN structure from −1100 V to 1100 V, while the P+P−N+ diode shows rectifying characteristics with an avalanche breakdown voltage of 1610 V. For example, FIG. 10 illustrates a graph of reverse characteristics of P+P−N+ diode with 1610 V breakdown.

When forming the positive-bevel termination, the p-n junction or Schottky barrier junction may be cut across such that more material is removed from the edge when progressing from a heavily doped side to a lightly doped side in the case of the p-n junction or a high work function side to a low work function side in the case of a Schottky barrier. Cutting may be implemented by use of, for example, but not limited to, a blade with two beveled edges like a V-shape or a trapezoidal shape, a blade with single beveled edge, a diamond-coated dicing wire, or the like. The cutting methods may include, but not limited to, a combined method of initial cutting of V-shaped trenches reaching a certain depth of the wafer and then using wet chemical etching or plasma etching techniques to enlarge/extend the trench surfaces to finish the structure. The positive-bevel termination may be a bevel angle lower than 90°, preferably 45° or lower.

In accordance with embodiments of the present disclosure, a semiconductor device with a negative-bevel termination may be manufactured. FIG. 11 illustrates a cross-sectional view of a semiconductor device that has a composite negative and positive-bevel terminations and manufactured in accordance with embodiments of the present disclosure. Referring to FIG. 11, the negative bevel reduces the surface electric field when the angle is very small and the higher doped side has a shallow gradient. The following equations may apply to the figure:

$${W}_{S} = \frac{{W}_{P}}{sin ( θ )}$$

$${E}_{mNB} = \frac{{V}_{A}}{{W}_{S}}$$

$${E}_{mB} = \frac{{V}_{A}}{{W}_{N}}$$

The surface electric field reduction may be defined by the following:

$${E}_{mNB} = {E}_{mB} ( \frac{{W}_{N}}{{W}_{S}} ) = {E}_{mB} \frac{{W}_{N}}{{W}_{P}} sin ( θ )$$

The negative bevel shown in FIG. 11 may be cut by a V-shaped blade, a blade with single bevel edge, laser dicing, a round edge blade, a wire dicing saw, or any other suitable cutting tool.

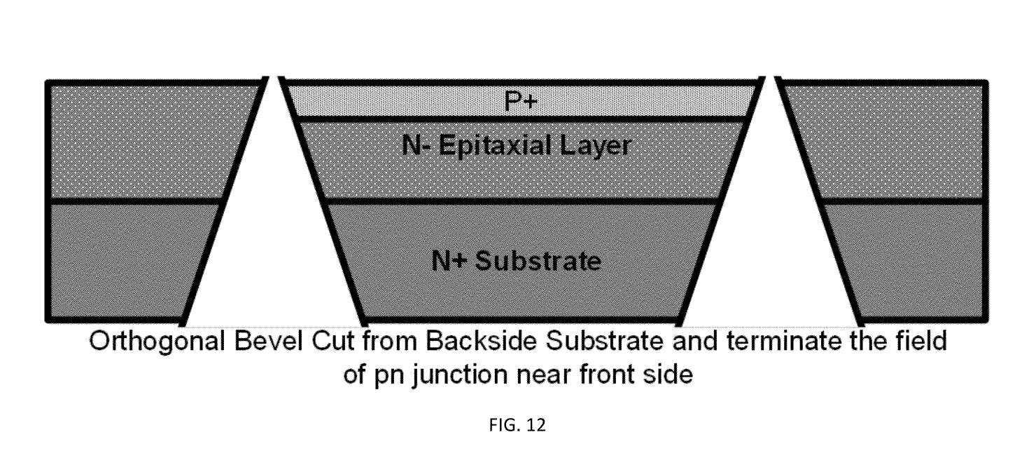

FIG. 12 illustrates a cross-sectional view of a P⁺N⁻N⁺ diode. The device may have a bevel cut from the backside substrate with the field of the p-n junction terminated near the front side. The application of reversely cutting the positive-bevel termination may be used as a forward blocking termination for any suitable device, such as a switch or diode. Cutting across the whole wafer thickness can introduce mechanical stresses that cause cracks in the devices. A multi-step processes might be adopted to make this structure with less such stress. The methods include, but not limited to, a combined method of initial cutting of V-shaped trenches reaching a certain depth from the surface and then using wet chemical etching or plasma etching techniques to enlarge/extend the trenches and finish the cut across the whole wafer thickness.

A semiconductor device having a negative-bevel termination may be manufactured by initially providing a wafer having disposed thereon a semiconductor device forming a p-n junction. Subsequently, a suitable cutting tool may be used to cut across the p-n junction to form the negative-bevel termination. The wafer may be any type of suitable semiconductor wafer.

In accordance with embodiments, a wafer may include an array of semiconductor devices that each have a p-n junction. Further, the dicing tool may be used to form another set of cuts across the p-n junctions that are in directions that are substantially orthogonal to the directions of the other cuts such that the negative-bevel termination is a substantially orthogonal negative-bevel termination. The cuts may also separate the semiconductor devices from one another. The semiconductor devices may be semiconductor switches, rectifiers, silicon devices, SiC devices, or other semiconductor devices. The negative-bevel termination may be a bevel angle of between about 1° and about 10°. The top-view crossing of negative-bevel termination may not be orthogonal but have an angle between about 45° and about 135° when the chip is not rectangle. The cutting may be performed such that more material is removed from the edge when progressing from a lightly doped side to a heavily doped side of the p-n junction.

In an example, a cutting tool or dicing tool such as, but not limited to, a dicing blade, a wire dicing saw, and a tilted layer beam to form multiple cuts across the p-n junctions to form the bevels. The cutting tool may be, for example, a V-shaped dicing blade having a flat bottom, a blade with a single beveled edge, a blade with a flat edge, a wire dicing saw, a tilted laser beam, or the like.

In another example, a surface of the negative-bevel termination may be etched for removing damage caused by the dicing tool. Etching may be by either wet etching the surface or dry etching the surface. In another example the technique may include etch-back after thermal oxidation. The etching may be performed subsequent to using the dicing tool.

Although many of the examples disclosed herein describe semiconductor devices having a p-n junction, the techniques disclosed herein may be similarly applied to semiconductor devices having a Schottky barrier junction or a heterojunction barrier. For example, cuts may be made across the Schottky barrier junction to form orthogonal positive-bevel terminations in accordance with embodiments disclosed herein.

Features from one embodiment or aspect may be combined with features from any other embodiment or aspect in any appropriate combination. For example, any individual or collective features of method aspects or embodiments may be applied to apparatus, system, product, or component aspects of embodiments and vice versa.

While the embodiments have been described in connection with the various embodiments of the various figures, it is to be understood that other similar embodiments may be used or modifications and additions may be made to the described embodiment for performing the same function without deviating therefrom. Therefore, the disclosed embodiments should not be limited to any single embodiment, but rather should be construed in breadth and scope in accordance with the appended claims.

What is claimed:

1. A method of manufacturing a semiconductor device, the method comprising:
providing a wafer having disposed thereon semiconductor layers forming one of a p-n junction and a Schottky barrier junction; and
cutting across the one of the p-n junction and the Schottky barrier junction for forming a substantially orthogonal positive-bevel termination.

2. The method of claim 1, wherein providing a wafer comprises providing a semiconductor wafer.

3. The method of claim 1, wherein the wafer comprises an array of semiconductor devices each having one of a p-n junction and a Schottky barrier junction, and
wherein using the dicing tool comprises using the dicing tool to form a first plurality of cuts across the one of the p-n junctions and the Schottky barrier junction of each of the semiconductor devices in the array.

4. The method of claim 3, wherein using the dicing tool comprises using the dicing tool to form a second plurality of cuts across the one of the p-n junctions and the Schottky barrier junction of each of the semiconductor devices in the array, wherein the second plurality of cuts are in directions that are substantially orthogonal to the directions of the first plurality of cuts such that the positive-bevel terminal is an orthogonal positive-bevel termination.

5. The method of claim 4, wherein the first and second plurality of cuts electrically separate the plurality of semiconductor devices from one another.

6. The method of claim 5, wherein the electrically separated semiconductor devices are one of power semiconductor switches and rectifiers.

7. The method of claim 3, wherein the semiconductor devices are one of SiC devices and silicon devices.

8. The method of claim 1, wherein the positive-bevel termination is at a bevel angle that is less than 90°.

9. The method of claim 1, wherein the dicing tool is one of a V-shaped dicing blade, a V-shaped dicing blade having a flat bottom, a dicing blade with single beveled edge, a wire dicing saw, and a laser dicing system.

10. The method of claim 1, further comprising etching a surface of the positive-bevel termination for one of removing damage caused by the dicing tool and enlarging the bevel/trench structure to a predetermined depth.

11. The method of claim 10, wherein etching the surface comprises one of wet etching the surface and dry etching the surface.

12. The method of claim 10, wherein etching is performed subsequent to using the dicing tool.

13. The method of claim 1, wherein cutting across the one of the p-n junction and the Schottky barrier junction comprises cutting across the junction such that more material is removed from the edge when progressing from a heavily doped side to a lightly doped side of the p-n junction or a high workfunction side to a low workfunction side of the Schottky barrier.

14. The method of claim 1, wherein cutting across the one of the p-n junction and the Schottky barrier junction comprises using a dicing tool or saw to cut across the p-n junction or Schottky barrier junction.

15. The method of claim 1, wherein the dicing tool or saw is one of a blade with two beveled edges like a V-shape or a trapezoidal shape, a blade with single beveled edge and a diamond-coated dicing wire.

16. The method of claim 1, wherein cutting across the one of the p-n junction and the Schottky barrier junction comprises using a tilted laser beam to cut across the one of the p-n junction and the Schottky barrier junction.

17. A semiconductor device being formed on a wafer having disposed thereon semiconductor layers forming one of a p-n junction and a Schottky barrier junction, and comprising a substantially orthogonal positive-bevel termination formed by cutting across the junction.

18. The semiconductor device of claim 17, wherein the wafer is a semiconductor wafer.

19. The semiconductor device of claim 17, wherein the semiconductor device is one of an array of semiconductor devices formed on the wafer and each having one of a p-n junction and a Schottky barrier junction, and
wherein the junctions are terminated with a first plurality of cuts made by the dicing tool cutting across the p-n junctions.

20. The semiconductor device of claim 18, wherein the junctions are terminated with a second plurality of cuts made by the dicing tool cutting across the junctions, wherein the second plurality of cuts are in directions that are substantially orthogonal to the directions of the first plurality of cuts such that the positive-bevel terminal is an orthogonal positive-bevel termination.

21. The semiconductor device of claim 20, wherein the first and second plurality of cuts electrically separate the plurality of semiconductor devices from one another.

22. The semiconductor device of claim 21, wherein the separated semiconductor devices are one of power semiconductor switches and rectifiers.

23. The semiconductor device of claim 19, wherein the semiconductor devices are one of SiC devices and silicon devices.

24. The semiconductor device of claim 17, wherein the positive-bevel termination is at a bevel angle that is less than 90°.

25. The semiconductor device of claim 17, wherein the dicing tool is one of a V-shaped dicing blade, a V-shaped dicing blade having a flat bottom, a dicing blade with single beveled edge, a wire dicing saw, and a laser dicing system.

26. The semiconductor device of claim 17, wherein the positive-bevel termination includes an etched surface.

27. The semiconductor device of claim 26, wherein the etched surface is formed by one of wet etching and dry etching.

28. The semiconductor device of claim 26, wherein the etched surface is etched subsequent to cutting across the junction to form the positive-bevel termination.

29. The semiconductor device of claim 17, wherein the cut is such that more material is removed from the edge when progressing from a heavily doped side to a lightly doped side of the p-n junction or a high workfunction side to a low workfunction side of the Schottky barrier.

30. The semiconductor device of claim 17, wherein the cut is performed by use of a dicing tool with or without wet/dry etching processes.

31. A method of manufacturing a semiconductor device, the method comprising:
providing a wafer having disposed thereon semiconductor device forming a p-n junction; and
cutting across the p-n junction for forming a substantial orthogonal negative-bevel termination.

32. The method of claim 31, wherein providing a wafer comprises providing a semiconductor wafer.

33. The method of claim 31, wherein the wafer comprises an array of semiconductor devices each having a p-n junction, and
wherein using the dicing tool comprises using one of a dicing blade, a wire dicing saw, and a tilted layer beam to form a first plurality of cuts across the p-n junctions.

34. The method of claim 33, wherein using the dicing tool comprises using the dicing tool to form a second plurality of cuts across the p-n junctions, wherein the second plurality of cuts are in directions that are substantially orthogonal to the directions of the first plurality of cuts such that the negative-bevel terminal is a substantially orthogonal negative-bevel termination.

35. The method of claim 34, wherein the first and second plurality of cuts separate the plurality of semiconductor devices from one another.

36. The method of claim 35, wherein the separated semiconductor devices are one of power semiconductor switches and rectifiers.

37. The method of claim 33, wherein the semiconductor devices are one of SiC devices and silicon devices.

38. The method of claim 31, wherein the negative-bevel termination is at a bevel angle of between about 1° and about 10°.

39. The method of claim 31, wherein the dicing tool is one of a V-shaped dicing blade having a flat bottom, a blade with single beveled edge, a blade with flat edge, a wire dicing saw, and a tilted laser beam.

40. The method of claim 41, further comprising etching a surface of the negative-bevel termination for removing damage caused by the dicing tool.

41. The method of claim 40, wherein etching the surface comprises one of wet etching the surface and dry etching the surface.

42. The method of claim 40, wherein etching is performed subsequent to using the dicing tool.

43. The method of claim 31, wherein cutting across the p-n junction comprises cutting across the p-n junction such that more material is removed from the edge when progressing from a lightly doped side to a heavily doped side of the p-n junction.

44. The method of claim 31, wherein cutting across the p-n junction comprises using a dicing tool to cut across the p-n junction.

45. The method of claim 31, wherein the negative-bevel termination has an orthogonal angle.

46. The method of claim 31, wherein the negative-bevel termination has an angle of between about 45° and 135°.

47. A semiconductor device being formed on a wafer having disposed thereon semiconductor layers forming a p-n junction, and comprising a negative-bevel termination formed by cutting across the p-n junction.

48. The semiconductor device of claim 47, wherein the wafer is a semiconductor wafer.

49. The semiconductor device of claim 47, wherein the semiconductor device is one of an array of semiconductor devices formed on the wafer and each having a p-n junction, and
wherein the p-n junctions are formed with a first plurality of cuts made by the dicing tool cutting across the p-n junctions.

50. The semiconductor device of claim 49, wherein the p-n junctions are formed with a second plurality of cuts made by the dicing tool cutting across the p-n junctions, wherein the second plurality of cuts are in directions that are substantially orthogonal to the directions of the first plurality of cuts such that the negative-bevel terminal is a substantially orthogonal negative-bevel termination.

51. The semiconductor device of claim 50, wherein the first and second plurality of cuts separate the plurality of semiconductor devices from one another.

52. The semiconductor device of claim 51, wherein the separated semiconductor devices are power semiconductor switches or rectifiers.

53. The semiconductor device of claim 49, wherein the semiconductor devices are one of SiC devices and silicon devices.

54. The semiconductor device of claim 47, wherein the negative-bevel termination is at a bevel angle of between about 1° and about 10°.

55. The semiconductor device of claim 47, wherein the dicing tool is one of a V-shaped dicing blade having a flat bottom, a blade with single beveled edge, a blade with flat edge, a wire dicing saw, and a tilted laser beam.

56. The semiconductor device of claim 47, wherein the negative-bevel termination includes an etched surface.

57. The semiconductor device of claim 56, wherein the etched surface is formed by one of wet etching and dry etching.

58. The semiconductor device of claim 56, wherein the etched surface is etched subsequent to cutting across the p-n junction to form the negative-bevel termination.

59. The semiconductor device of claim 47, wherein the negative-bevel termination is formed by cutting across the p-n junction such that more material is removed from the edge when progressing from a lightly doped side to a heavily doped side of the p-n junction.

60. The semiconductor device of claim 47, wherein the cut is performed by use of a dicing tool to cut across the p-n junction.

61. The semiconductor device of claim 47, wherein the corners of negative-bevel termination have orthogonal angles.

62. The semiconductor device of claim 47, wherein corners of the negative-bevel termination have angles of between about 45° and about 135°.

63. A method of manufacturing a semiconductor device, the method comprising:
providing a wafer having disposed thereon semiconductor layers forming a p-n junction; and
cutting across the p-n junction for forming an angled positive-bevel termination.

64. The method of claim 63, wherein cutting across the p-n junction forms the positive-bevel termination with an angle smaller than 90°.

65. A semiconductor device being formed on a wafer having disposed thereon semiconductor layers forming a p-n junction, and comprising an angled positive-bevel termination formed by cutting across the p-n junction.

66. The semiconductor device of claim 65, wherein the corners of positive-bevel termination have angles of between about 45° and about 135°.
